(19) United States
(12) Patent Application Publication
(10) Pub. No.: US 2009/0074101 A1
(43) Pub. Date: Mar. 19, 2009

(54) Detection Performance in Communication Systems

(75) Inventors: XiangGuo Tang, Union City, CA (US); Jun Shen, Palo Alto, CA (US)

Correspondence Address: Venture Pacific Law, PC, 5201 Great America Parkway, Suite 270, Santa Clara, CA, 95054, US

(73) Assignee: APACEWAVE TECHNOLOGIES CORPORATION, Fremont, CA (US)

(21) Appl. No.: 11/856,645

(22) Filed: Sep. 17, 2007

(51) Int. Cl. H03C 5/00

(52) U.S. Cl. 375/268

(57) ABSTRACT

A method and system to generate decoded information from received symbols in communication receivers. A first embodiment is a method to detect digitally modulated symbols and generate decoded information. The method includes receiving digitally modulated symbols, demapping the digitally modulated symbols to generate soft decisions representing digitally modulated symbols, multiplying the soft decisions by an adaptive factor to generate scaled soft decisions; and decoding the scaled soft decisions to generate decoded information. A second embodiment is a system having modules to detect digitally modulated symbols and generate decoded information. These embodiments can be applied in several wired and wireless communication applications including, but not limited to, WiMAX applications.

### BACKGROUND OF THE INVENTION

1. Field of the Invention

This invention relates to voice and data communications, and more particularly to systems and methods to process received signals in communication systems.

2. Description of the Prior Art

The Institute of Electrical and Electronic Engineers (IEEE) has established a communication standard, IEEE 802.16e. The IEEE 802.16e standard (IEEE 802.16e) outlines Media Access Control (MAC) and Physical Layer (PHY) specifications for communication networks. In particular, the IEEE 802.16e standard addresses communication in wireless asynchronous transfer mode (ATM) systems, covering frequencies of operation between 2.5 gigahertz (GHz) and 6 GHz. As is known in the art, IEEE 802.16e uses a modulation method called orthogonal frequency-division multiplexing access (OFDMA), which allows communication to occur at extremely high data speeds by transmitting data over multiple frequency channels over a wide frequency range.

The IEEE 802.16e specification includes mechanisms to maximize data transmission and reception reliability in packet transmission. Typically, several processes are performed in the receiver to ultimately receive the transmitted data, including: synchronization, channel estimation and equalization, OFDM demodulation (e.g., by Fast Fourier Transforms), demapping, de-interleaving, decoding, and descrambling. The more relevant sections of the IEEE 802.16e specification for the discussion below include sections 8.4.2, 8.4.4, 8.4.6, and 8.4.9, which are hereby incorporated by reference.

The detection performance of wireless and wired receiving systems, especially for higher order modulation symbols, plays a crucial role. For example, in OFDM communication receiver systems detection performance is very critical for reliable links between the transmitter and the receiver. One example wireless communication network system is disclosed in the Mobile WiMAX Technical Overview and Performance Evaluation document prepared on behalf of the WiMAX Forum and published on Feb. 21, 2006, which is hereby incorporated by reference.

One paper that suggests the substantial challenges in minimizing errors for acceptably reliable reception in wireless and wired communication systems is entitled “Soft Decision Metric Generation for QAM With Channel Estimation Error,” written by Michael Mao Wang, Weimin Xiao, and Tyler Brown, and published in the IEEE Transactions on Communications, Vol. 50, No. 7, pp. 1058-1061, (July 2002), which is hereby incorporated by reference. This paper discusses the bit error rate (BER) performance using hard decisions and soft decisions (representing the code bit log likelihood ratio for soft decision decoding from symbols such as quadrature amplitude modulation (QAM) symbols). In practice the soft decisions are quantized by a finite number of bits, where a significant number of bits are required for acceptable reception reliability (e.g., an acceptable BER, and/or other channel reception quality metrics).

There are existing schemes for the detection of high order modulation symbols, but they require a significant number of bits as input to a decoder to provide the decoded bits. Typically, the decoder generates the decoded bits from soft decision bits. In practice, the soft decision is quantized by finite number of bits. In general, the number of soft decision bits required to represent the soft decision for higher order modulation symbols is more than that required by lower order modulation symbols, because higher order modulation symbols {e.g., quadrature amplication symbols (e.g., 16QAM and 64QAM symbols), or equivalent symbols} have a larger dynamic range.

The number of soft decision bits determines the necessary memory size and computational complexity of the decoder {e.g., a forward error correction (FEC) decoder, other type of decoder, or a decoder equivalent}. However, the detection methods presently used require relatively large memory for adequate performance. In a typical communication receiver, a soft demapper directly provides soft decisions to a FEC decoder. If insufficient number of soft bits is used for higher order modulation symbols, the communication receiver performance will degrade.

FIG. 1 illustrates a flowchart of a method to process a digitally modulated symbol, according to the prior art. The sequence starts in operation 102. Operation 104 is next and includes demapping a digitally modulated symbol with a soft demapper. Operation 106 is next and includes decoding the demapping output with a decoder. The method ends in operation 108.

One example of a current receiving system is illustrated in FIG. 2. Soft demapper module 202 receives a digitally modulated symbol 204 and produces a digital output 206 that is coupled to a decoder module 208 to produce decoded bits 210 as an output. However, as previously noted, this decoder module uses significant memory. This digitally modulated symbol reception challenge exists with several types of wireless systems.

At higher frequencies the signal is more directional and more easily interrupted by relative movements of the transmitter and/or receiver. Furthermore, at higher frequencies the amount of data transmitted in a unit of time increases, creating a need to avoid or minimize interruptions due to failures in reception. Therefore, a reception algorithm should be optimized as much as possible to deal with the greater vulnerabilities and consequences of higher frequency and faster data transmission environments.

In view of the foregoing, what is needed is an improved method and system to process received digitally modulated symbols. Various wired and wireless wideband and narrowband reception applications could benefit from such methods and systems.

### SUMMARY OF THE INVENTION

The present invention can be implemented in numerous ways, such as by a method, a circuit, or a system. Two aspects of the invention are described below.

A first aspect of the invention is directed to a method to detect digitally modulated symbols and generate a plurality of decoded information bits. The method includes receiving a plurality of digitally modulated symbols, demapping the plurality of digitally modulated symbols to generate a plurality of soft decisions representing the plurality of digitally modulated symbols, multiplying the plurality of soft decisions by an adaptive factor to generate a plurality of scaled soft decisions; and decoding the plurality of scaled soft decisions to generate decoded information.

A second aspect of the invention is directed to a system to detect digitally modulated symbols and generate a plurality of decoded information bits. The system includes a module for demapping a plurality of digitally modulated symbols to generate a plurality of soft decisions representing the plurality of digitally modulated symbols, a multiplier module to multiply the plurality of soft decisions by an adaptive factor to generate a plurality of scaled soft decisions; and a decoder module to decode the plurality of scaled soft decisions to generate decoded information.

These and other objects and advantages of the invention will become apparent to those skilled in the art from the following detailed description of the invention and the accompanying drawings.

### BRIEF DESCRIPTION OF THE DRAWINGS

FIG. 1 illustrates a flowchart of a conventional process to detect digitally modulated symbols and generate decoded information, in accordance with the prior art.

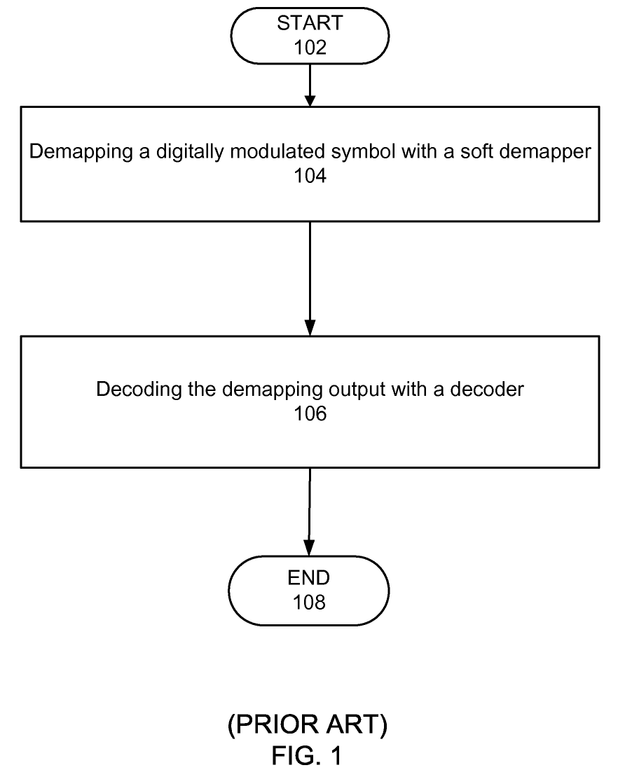

FIG. 2 illustrates a receiving system to detect digitally modulated symbols and generate decoded information, in accordance with the prior art.

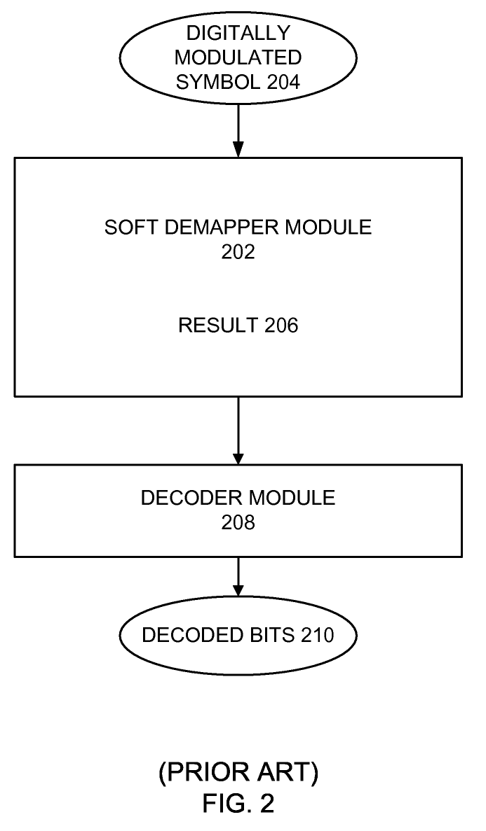

FIG. 3 illustrates a flowchart of a process to detect digitally modulated symbols and generate decoded information, according to one embodiment of the invention.

FIG. 4 illustrates a block diagram of a system to detect digitally modulated symbols and generate decoded information, according to one embodiment of the invention.

FIG. 5 illustrates a flowchart of a process to detect digitally modulated symbols and generate decoded information, according to another embodiment of the invention.

FIG. 6 illustrates a block diagram of a system to detect digitally modulated symbols and generate decoded information, according to another embodiment of the invention.

FIG. 7 illustrates a flowchart of the process to detect digitally modulated symbols and generate decoded information, according to another embodiment of the invention.

FIG. 8 illustrates a block diagram of a system to detect digitally modulated symbols and generate decoded information, according to another embodiment of the invention.

### DETAILED DESCRIPTION OF THE PREFERRED EMBODIMENT

The invention provides a method and a system to improve the detection of digitally modulated symbols and the generation of decoded information in wired and wireless communication systems. Various embodiments of the invention can be applied to communication applications, biological applications, medical applications, electronic applications, and any other applications where such methods and systems can be beneficially used in communications. In this specification, drawings, and claims, any instance of the term radio-frequency is defined as any electromagnetic signal frequency in the frequency range of 50,000 to 100,000,000,000 cycles per second (Hertz).

Other terms used below or in the figures are defined as follows. QPSK represents quadrature phase shift keying. QAM represents quadrature amplitude modulation, and variants include 16QAM and 64QAM. BER represents bit error rate. FEC decoder represents a forward error correction decoder. AWGN channel represents an additive white Gaussian noise channel model. ITU Veh A represents the International Telecommunication Union vehicle channel model. Further explanation on terminology and technology is disclosed in the Mobile WiMAX Technical Overview and Performance Evaluation document prepared on behalf of the WiMAX Forum and published on Feb. 21, 2006, which is hereby incorporated by reference; and the IEEE 802.16e specification (both the 2004 version and the 2005 amendment), particularly sections 8.4.2, 8.4.4, 8.4.6, and 8.4.9; which are also hereby incorporated by reference. However, the scope of the invention should not be considered to be limited only to communication receivers in accordance to these technical specifications. Certain embodiments of the invention are also applicable to cable communications, and other wired and wireless communications.

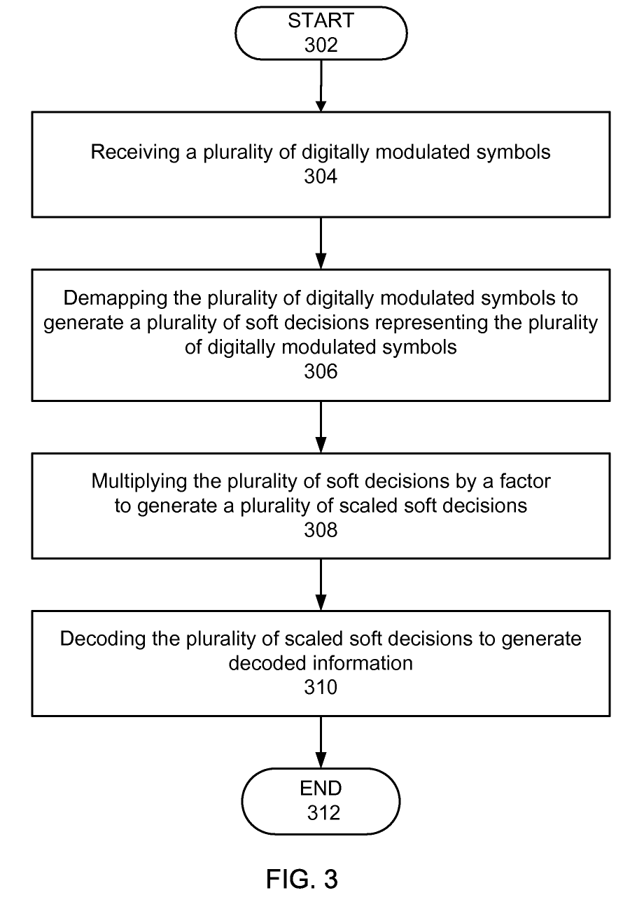

FIG. 3 illustrates a flowchart of a method to detect digitally modulated symbols and generate decoded information, according to one embodiment of the invention. The sequence starts in operation 302. Operation 304 is next and includes receiving a plurality of digitally modulated symbols (e.g., 16QAM symbols, 64QAM symbols, QPSK symbols, or equivalent digitally modulated symbols). Operation 306 is next and includes demapping the plurality of digitally modulated symbols to generate a plurality of soft decisions representing the plurality of digitally modulated symbols. Operation 308 is next and includes multiplying the plurality of soft decisions by a factor (e.g., an adaptive factor, or a fixed factor, or an equivalent) to generate a plurality of scaled soft decisions. Operation 310 is next and includes decoding the plurality of scaled soft decisions to generate decoded information. The method ends in operation 312.

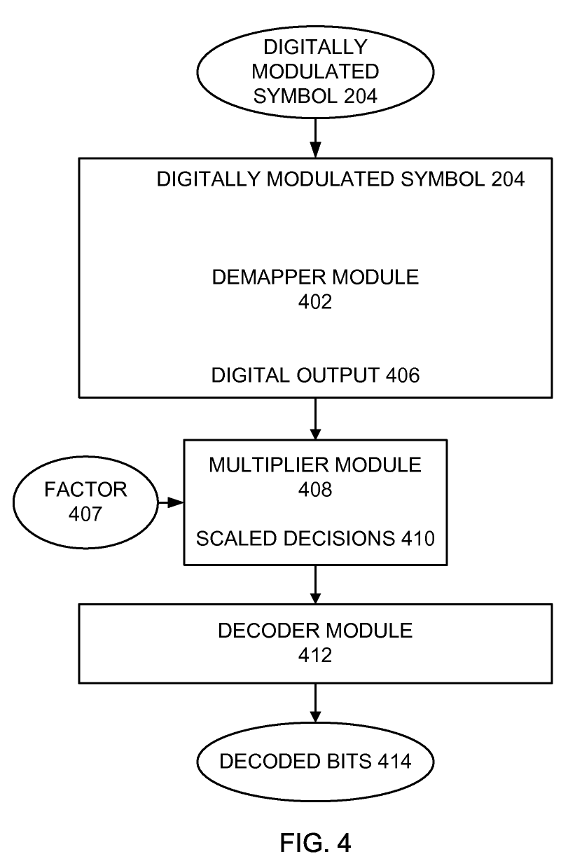

FIG. 4 is a block diagram illustrating major modules of a system to detect digitally modulated symbols and generate decoded information, according to one embodiment of the invention. A demapper module 402 receives digitally modulated symbols 204 and produces a digital output 406. The digital output 406 is coupled as an input, along with factor 407 as a second input, to multiplier module 408 that outputs scaled soft decisions 410 to decoder module 412. Decoder module 412 outputs decoded bits 414 for further processing by the remainder of the receiving system.

In certain embodiment, the demapper module 402 is implemented by any module that can perform the demapping operation from the digitally modulated symbols 204 to produce the digital output 406. In certain embodiments of the invention, the demapper module 402 is a soft demapper, a hard demapper, a combination of demapper modules, or any equivalent module that can achieve a demapping of the digitally modulated symbols 204. In certain embodiments of the invention, the multiplier module 408 is an actual multiplier (e.g., a 12 bit by 12 bit multiplier, or an equivalent multiplier), a shift register, a mask register, or an equivalent module that can achieve a defacto multiplication by either shifting bits, reclassifying bits, or by actual multiplication. In certain embodiments, the decoder module 412 is an actual decoder, such as a forward error correction (FEC) decoder, or an equivalent module (e.g., a combinational logic module and/or sequential logic module) that can produce appropriate bit output from the scaled soft decisions 410.

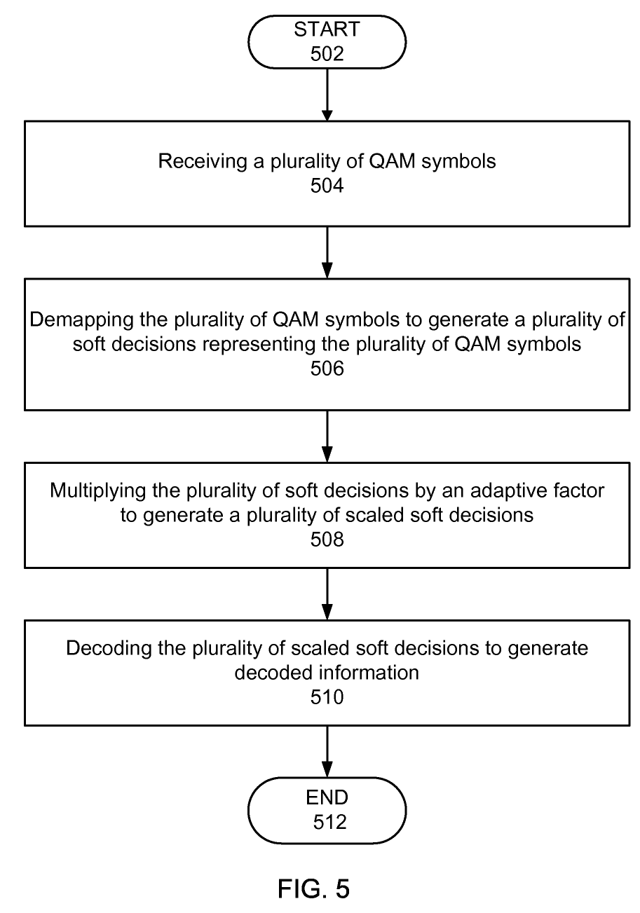

FIG. 5 illustrates a flowchart of a method to detect digitally modulated symbols and generate decoded information, in accordance with another embodiment of the invention. The sequence starts in operation 502. Operation 504 is next and includes receiving a plurality of digitally modulated symbols. Operation 506 is next and includes demapping the plurality of digitally modulated symbols to generate a plurality of soft decisions representing the plurality of digitally modulated symbols. Operation 508 is next and includes multiplying the plurality of soft decisions by an adaptive factor to generate a plurality of scaled soft decisions. Operation 510 is next and includes decoding the plurality of scaled soft decisions to generate decoded information. The method ends in operation 512.

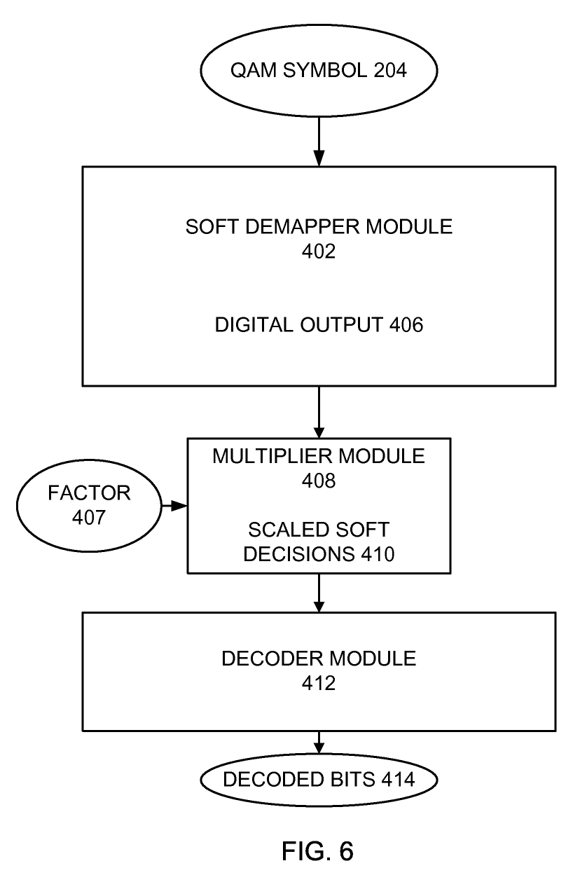

FIG. 6 illustrates a system to detect digitally modulated symbols and generate decoded information, in accordance with another embodiment of the invention. A soft demapper module 602 receives digitally modulated symbols 204 and produces a digital output 406. The digital output 406 is coupled as an input, along with factor 407 as a second input, to multiplier module 408 that outputs scaled soft decisions 410 to decoder module 412. Decoder module 412 outputs decoded bits 414 for further processing by the remainder of the receiving system.

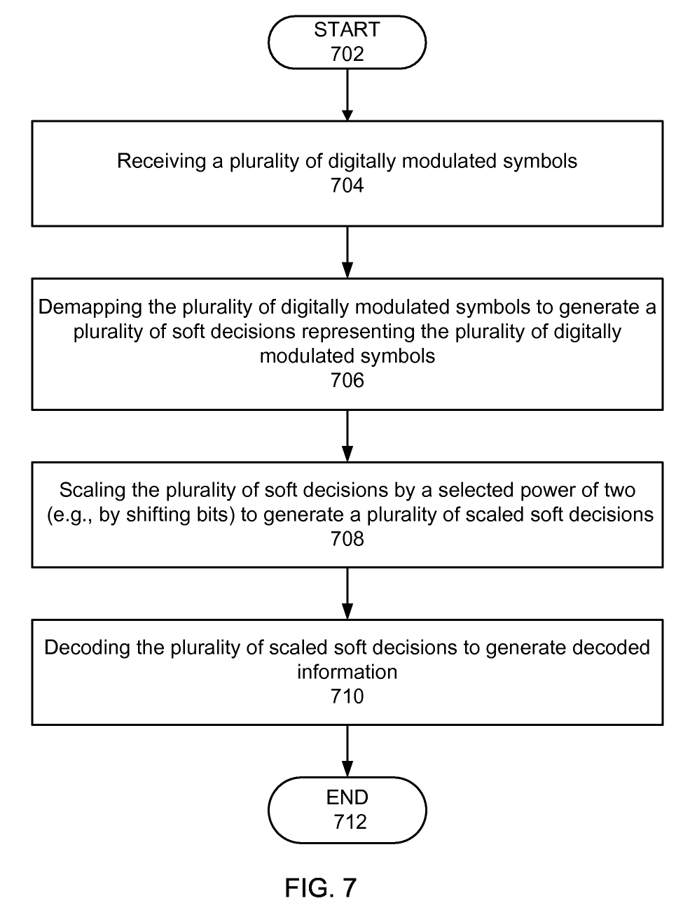

FIG. 7 illustrates a flowchart of a method to detect digitally modulated symbols and generate decoded information, in accordance with another embodiment of the invention. The sequence starts in operation 702. Operation 704 is next and includes receiving a plurality of digitally modulated symbols. Operation 706 is next and includes demapping the plurality of digitally modulated symbols to generate a plurality of decisions representing the plurality of digitally modulated symbols. Operation 708 is next and includes multiplying the plurality of decisions by an adaptive factor to generate a plurality of scaled decisions. Operation 710 is next and includes decoding the plurality of scaled decisions to generate decoded information. The method ends in operation 712.

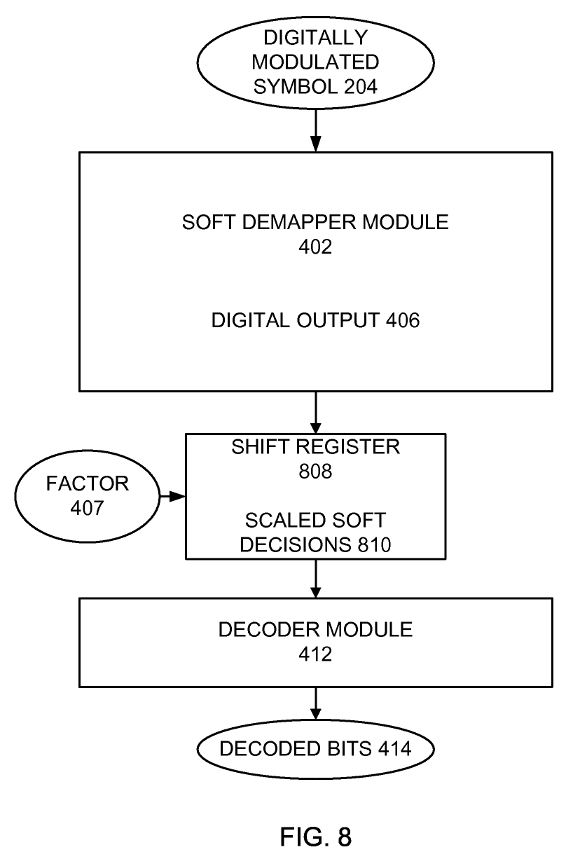

FIG. 8 illustrates a system to detect digitally modulated symbols and generate decoded information, according to another embodiment of the invention. A soft demapper module 402 receives digitally modulated symbols 204 and produces a digital output 406. The digital output 406 is coupled as an input, along with factor 407 as a second input, to a multiplier module (in this embodiment a register 808) that outputs scaled decisions 410 to decoder module 412. Decoder module 412 outputs decoded bits 414 for further processing by the remainder of the receiving system.

In certain embodiments of the invention, the factor can be 1, 2, 4, 8 or any number depending on the modulation scheme, modulation order, coding rate, or channel condition, or any combination of the preceding. In one embodiment, the factor is a 1 for a QPSK modulation scheme, the factor is a 2 for a 16QAM modulation scheme, and the factor is a 4 for a 64QAM modulation scheme.

In higher order modulation schemes, the insufficient number of soft bits limits the resolution of the soft decision, particularly on the least significant bits (LSB). Multiplying the soft decision increases the resolution of soft decision for the LSB. Although in some embodiments the soft decision for the most significant bits (MSB) may be clipped (i.e., saturated) after the multiplication, the overall FEC decoding performance is improved. For one embodiment having a 4 bit soft demapper with the 64QAM-3/4 CTC code specified in IEEE802.16e specification (of 2005), more than 0.5 dB gain is observed for an additive white Gaussian noise (AWGN) channel, and more than 2 dB gain is observed by multiplying by a factor of 8 in the case of an ITU Veh-A 60 Km/hr fading channel.

Several embodiments of the invention are possible. The phrase “in one embodiment” used in the specification can refer to a new embodiment, a different embodiment disclosed elsewhere in the application, or the same embodiment disclosed earlier in the application. The exemplary embodiments described herein are for purposes of illustration and are not intended to be limiting. Therefore, those skilled in the art will recognize that other embodiments could be practiced without departing from the scope and spirit of the claims set forth below.

What is claimed is:

1. A method to detect digitally modulated symbols and generate a plurality of decoded information bits, comprising:
receiving a plurality of digitally modulated symbols;
demapping the plurality of digitally modulated symbols to generate a plurality of soft decisions representing the plurality of digitally modulated symbols;
multiplying the plurality of soft decisions by a factor to generate a plurality of scaled soft decisions; and
decoding the plurality of scaled soft decisions to generate decoded information.

2. The method of claim 1 wherein the multiplying step is carried out by shifting the soft decisions.

3. The method of claim 1 wherein the factor is selected as a function of the modulation scheme, modulation order, coding rate, and channel condition.

4. The method of claim 3 wherein the value of the factor is in direct correlation with the value of the modulation order.

5. The method of claim 3 wherein the value of the factor is in direct correlation with the value of the code rate.

6. The method of claim 3 wherein the value of the factor is in direct correlation with the channel condition.

7. The method of claim 3 wherein the value of the factor is in direct correlation with the modulation scheme.

8. The method of claim 1, wherein the plurality of digitally modulated symbols include at least one quadrature amplitude modulation symbol.

9. The method of claim 1, wherein the decoding of the plurality of scaled soft decisions includes decoding by a forward error correction decoder.

10. The method of claim 1, wherein the demapping of the digitally modulated symbol includes soft demapping to produce the digital output.

11. A system to detect digitally modulated symbols and generate a plurality of decoded information bits, comprising:
a demapping module to receive a plurality of digitally modulated symbols and demapp the plurality of digitally modulated symbols to generate a plurality of soft decisions representing the plurality of digitally modulated symbols;
a multiplier module to multiply the plurality of soft decisions by a factor to generate a plurality of scaled soft decisions; and
a decoder module to decode the plurality of scaled soft decisions to generate decoded information.

12. The system of claim 11 wherein the multiplier module includes a shift register.

13. The system of claim 11 wherein the factor is selected as a function of the modulation scheme, modulation order, coding rate, and channel condition.

14. The system of claim 13 wherein the value of the factor is in direct correlation with the value of the modulation order.

15. The system of claim 13 wherein the value of the factor is in direct correlation with the value of the code rate.

16. The system of claim 13 wherein the value of the factor is in direct correlation with the channel condition.

17. The system of claim 13 wherein the value of the factor is in direct correlation with the modulation scheme.

18. A method to detect digitally modulated symbols and generate a plurality of decoded information bits, comprising:
receiving a plurality of digitally modulated symbols;
demapping the plurality of digitally modulated symbols to generate a plurality of decision bits representing the plurality of digitally modulated symbols;
multiplying the plurality of decision bits by an adaptive factor to generate a plurality of scaled decision bits; and
decoding the plurality of scaled soft decisions to generate a plurality of decoded information bits.

19. The method of claim 18 wherein the multiplying step is carried out by shifting the decision bits.

20. The method of claim 18 wherein the adaptive factor is selected as a function of the modulation scheme, modulation order, coding rate, and channel condition.
